(19) United States
(12) Patent Application Publication
(10) Pub. No.: US 2022/0317243 A1
(43) Pub. Date: Oct. 6, 2022

(54) PRESSURE COMPENSATION ELEMENT, HOUSING, SENSOR ASSEMBLY AND MOTOR VEHICLE

(71) Applicant: Conti Temic microelectronic GmbH, Nürnberg (DE)

(72) Inventors: Markus Thai, Ulm (DE); Rodrigo Hernan Barbano, Blaustein (DE); Erwin Ehinger, Heidenheim (DE)

(73) Assignee: Conti Temic microelectronic GmbH, Nürnberg (DE)

(21) Appl. No.: 17/597,981

(22) PCT Filed: Mar. 4, 2020
(86) PCT No.: PCT/DE2020/200014

§ 371 Date: Jan. 31, 2022

(30) Foreign Application Priority Data
Jul. 29, 2019 (DE) 10 2019 211 249.8

(51) Int. Cl. G01S 7/02; G01S 13/931

(52) U.S. Cl. CPC G01S 7/027; G01S 13/931

(57) ABSTRACT

A pressure compensation element includes a plastic part and a membrane, wherein the plastic part has an upper and an underside and at least one hole extending from the upper to the underside. At least one hole is formed in an offset manner and/or in that at least one bridge-type element is arranged on the upper or the underside of the plastic part, and extends over the at least one hole

### TECHNICAL FIELD

The technical field relates to a pressure compensation element, a housing, a sensor assembly and a motor vehicle.

### BACKGROUND

Pressure compensation elements are known in a great number of documents from the prior art. Pressure compensation elements make it possible for gases, in particular, to make their way outwardly from the inside of a housing and, simultaneously, prevent liquids penetrating the housing.

It is desirable to provide an improved pressure compensation element, in which the functionality of an arranged membrane can in particular be guaranteed.

### SUMMARY

According to a first aspect, a pressure compensation element includes a plastic part and a membrane, wherein the plastic part has an upper and an underside and at least one hole extending from the upper to the underside. The at least one hole is formed in an offset manner and/or in that at least one bridge-type element is arranged on the upper or the underside of the plastic part, and extends over the at least one hole.

In particular, the pressure compensation element ensures that a membrane arranged on the plastic part is reliably protected against external influences. Both the offset hole and the bridge-type element ensure that the membrane is not directly exposed to the external influences.

In accordance with the disclosure, the term “in an offset manner” is in particular to be understood to mean that an inlet of the hole and an outlet of the hole are not arranged in a planar manner above one another, but rather are displaced with respect to one another. That is to say that the matter which would like to pass through the hole cannot simply flow straight through the hole, but rather has to flow around a corner or bend, in particular. According to one configuration, the at least one hole is formed in a graduated or angled manner.

The bridge-type element may be formed in such a manner that, when looking vertically at the upper side or vertically at the underside of the plastic part, the at least one hole cannot be seen. That is to say that the bridge-type element covers or spans the at least one hole.

The bridge-type element can be substantially connected at one of its ends to the upper or underside of the plastic part. It is, however, also possible that the bridge-type element is substantially connected at both of its ends to the upper or the underside of the plastic part. The bridge-type element substantially has a stirrup-shaped or bridge-shaped configuration. The bridge-type element and the plastic part are preferably integrally formed.

The plastic part can be formed from a thermoplastic. The plastic part is preferably formed from polybutylene terephthalate (PBT). The plastic part is may be glass fiber reinforced or formed from a glass fiber-reinforced polybutylene terephthalate.

The membrane can be arranged both on the upper side and on the underside of the plastic part. This brings with it the advantage that the pressure compensation element can be mounted both on an outside of a housing or from the outside on a housing or housing part and on an inside of a housing or from the inside on a housing or housing part. The area of application of the pressure compensation element is therefore very wide.

It is advantageous if the plastic part has a multiplicity of holes. The multiple holes are in particular arranged on a circular arc, preferably on a circular path. If the plastic part has multiple holes, then at least one of the holes is in particular formed in an offset manner. All of the holes are advantageously formed in an offset manner. The holes are preferably arranged at a uniform distance from one another and/or are formed similarly.

In one configuration, the plastic part has at least one cavity. The cavity serves in particular to receive the membrane or the membrane is arranged in the cavity. The cavity preferably has a depth and/or an extent which substantially corresponds to the thickness or the extent of the membrane. The cavity can be arranged on the upper side or on the underside of the plastic part. It is advantageous if a cavity is arranged on each of the two sides.

The plastic part can have a collar-shaped region. In particular, the collar-shaped region serves as a connection region. A connection of the plastic part to a further element, in particular to a housing or a housing part, can be produced via the connection region. The connecting is effected in particular by means of an adhesive connection. However, it is also conceivable that a connection is effected by thermal direct joining or welding. The plastic part advantageously has a circumferential collar-shaped region. Ideally, the plastic part is substantially formed in the shape of a flange.

It is advantageous if the plastic part has at least one spacer element. In particular, the spacer element serves to define the maximum or minimum thickness of a connection layer, such as an adhesive layer. In particular, the at least one spacer element is arranged in the region which is formed in the shape of a collar. In principle, no fixed shape of the spacer element is specified. It is advantageous if the spacer element has a substantially circular form. The plastic part advantageously has a multiplicity of spacer elements. The spacer elements are in particular arranged at a uniform distance from one another; this is in particular to be understood to mean that a similar distance exists between the individual spacer elements.

In one configuration, the plastic part has at least one groove and/or one lamella, preferably a curved groove and/or a curved lamella, particularly preferably a circumferential groove and/or a circumferential lamella. In particular, the groove or lamella has a sealing effect. It is advantageous if a multiplicity of grooves or lamellae, in particular a multiplicity of circumferential grooves or circumferential lamellae, are provided and these are arranged in particular adjacent to one another. The groove or the lamella is preferably arranged in the collar-shaped region of the plastic part. At least one groove or lamella is advantageously arranged on both sides of the collar-shaped region.

The plastic part is in principle not restricted to any specific shape or contour. In one configuration, the plastic part is substantially formed in the shape of a circle.

The membrane has in particular an operating temperature range between −40° C. and +125° C. It is advantageous if the membrane is formed in such a manner that it can withstand a minimum water pressure of 60 kPA for at least 30 seconds. The membrane is preferably formed from a water-repellent and/or oil-repellent expanded polytetrafluorethylene (PTFE). In particular, the membrane has a carrier made of a nonwoven polyester fabric.

The membrane and the plastic part may be connected to one another by means of a weld connection. The advantage of a weld connection between the plastic part and the membrane is that this can guarantee an extremely high level of waterproofness.

According to a second aspect, the disclosure relates to a housing having at least one housing part and a pressure compensation element, wherein the housing part has a hole and the pressure compensation element is arranged in the hole.

In particular, the housing ensures a secure and reliable pressure compensation between the internal space of the housing and the surroundings.

The pressure compensation element can be arranged both on an inside of the housing part or of the housing and on an outside of the housing part or of the housing.

The housing part and the pressure compensation element may be connected to one another via an adhesive connection. The adhesive connection is in particular located between the collar-shaped region of the plastic part or the circumferential collar of the plastic part and the housing part.

The housing part may be formed from a metal.

According to a third aspect, the disclosure relates to a sensor assembly having a sensor element and a housing, wherein the housing encloses the sensor element. It is advantageous if the housing isolates the sensor element from the surroundings. The sensor element can be a radar sensor, a lidar sensor, an ultrasonic sensor or a camera assembly.

According to a fourth aspect, the disclosure relates to a motor vehicle having a sensor assembly according to the invention.

### BRIEF DESCRIPTION OF THE DRAWINGS

Further advantageous configurations are set out in the drawings, wherein:

FIG. 1: shows a schematic representation of a plastic part of a pressure compensation element according to the invention according to a first configuration;

FIG. 2: shows a sectional representation of the plastic part from FIG. 1;

FIG. 3a: shows a view of an underside of the plastic part from FIG. 1;

FIG. 3b: shows a view of an upper side of the plastic part from FIG. 1;

FIG. 4: shows a schematic representation of a pressure compensation element according to the invention in a configuration;

FIG. 5: shows a schematic representation of a plastic part in a further configuration; and

FIG. 6: shows an exploded representation of a housing according to the invention in a configuration.

### DETAILED DESCRIPTION

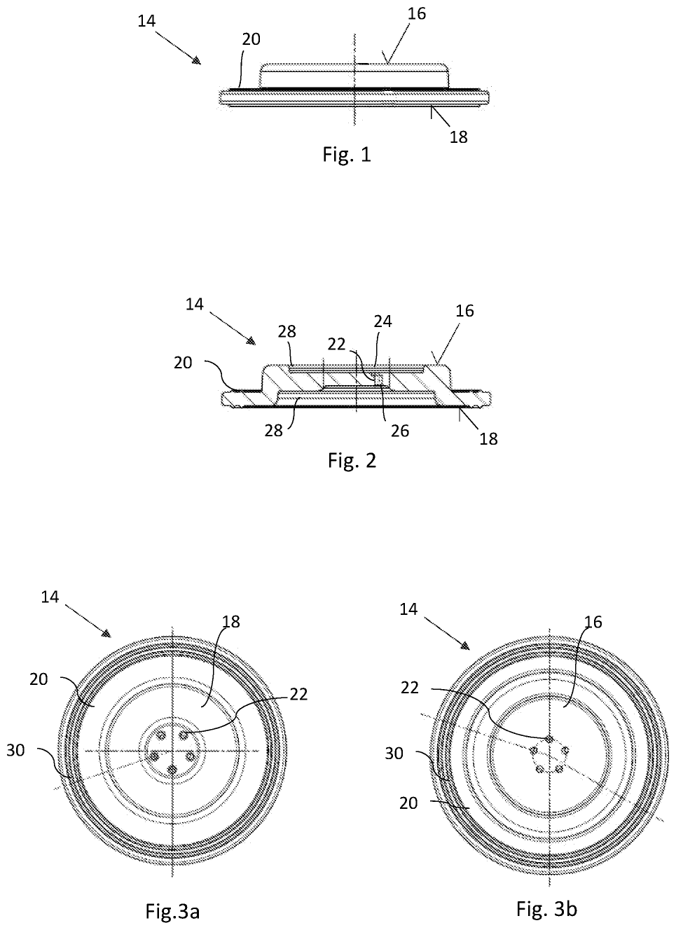

FIG. 1 shows a schematic representation of a plastic part 14 of a pressure compensation element according to a first configuration. The plastic part 14 has an upper side 16 and an underside 18 and a circumferential collar 20. The circumferential collar 20 serves in particular to connect the plastic part 14 to other elements such as, for example, a housing part. The plastic part 14 may be formed from a polybutylene terephthalate.

FIG. 2 shows a sectional representation of the plastic part 14 from FIG. 1. The plastic part 14 has a cavity 28, in each case, both on the upper side 16 and on an underside 18. The cavity 28 serves in particular to receive the membrane. The plastic part 14 also has at least one hole 22. The hole 22 extends from the upper side 16 of the plastic part 14 up to the underside 18 of the plastic part 14, wherein the hole 22 is formed in an offset or stepped manner, as a result of which an inlet 24 of the hole 22 and an outlet 26 of the hole 22 do not lie above one another in a planar manner, but rather are arranged displaced with respect to one another.

FIG. 3a shows a view of an underside 18 of the plastic part 14 from FIG. 1. A multiplicity of holes 22, which are arranged on a circular path, can be seen. The holes 22 are in particular holes formed in an offset manner. The circumferential collar 20 can also be seen, wherein circumferential lamellae 30 are arranged on the collar 20.

FIG. 3b shows a view of an upper side 16 of the plastic part 14 from FIG. 1. A multiplicity of holes 22, which are arranged on a circular path, can be seen. The holes 22 are in particular holes formed in an offset manner. Here as well, the circumferential collar 20 can also be seen, wherein circumferential lamellae 30 are in turn arranged on the collar 20.

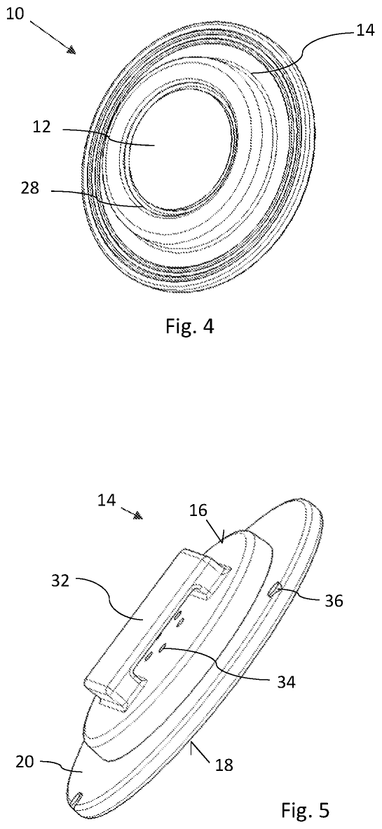

FIG. 4 shows a schematic representation of a pressure compensation element 10 according to the invention in a configuration. The pressure compensation element 10 comprises a plastic part 14, in particular a plastic part 14, as has been described regarding the preceding figures, and a membrane 12. The membrane 12 is arranged in a recess 28 of the plastic part 14 which is located on the upper side of the plastic part 14. However, it is also conceivable that the membrane is not arranged on the upper side, but rather on the underside of the plastic part 14. The arrangement of the membrane on the plastic part depends in particular on the intended purpose of the pressure compensation element.

FIG. 5 shows a schematic representation of a plastic part 14 in a further configuration. The plastic part 14 has a multiplicity of holes 34, wherein the holes 34 are in particular formed in a straight line. This is in particular to be understood to mean that the inlet and the outlet of a hole 34 are aligned with one another. The plastic part 14 also has a bridge-type element 32 on its upper side 16. The bridge-type element 32 is formed in such a manner that, when looking vertically at the upper side 16 of the plastic part 14, the at least one hole 34 is not visible to the observer. That is to say that the bridge-type element 32 covers or spans the hole 34. The bridge-type element 32 is connected at its two ends to the upper side 16 of the plastic part 14, as a result of which the bridge-type element 32 substantially has a bridge-shaped configuration. The bridge-type element 32 and the plastic part 14 are preferably integrally formed. Furthermore, the plastic part 14 additionally has spacer elements 36. The spacer elements 36 are arranged at least on one side of the circumferential collar 20. The spacer elements 36 are preferably a uniform distance from one another. The spacer elements 36 are in particular formed in the shape of a pin.

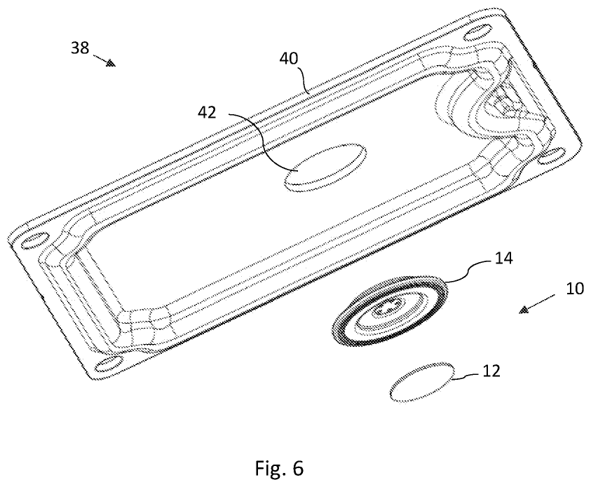

FIG. 6 shows an exploded representation of a housing 38 according to a configuration. The housing 38 comprises at least one housing part 40 which is in particular formed from a metal, and a pressure compensation element 10. The housing part 40 comprises a hole 40 which is formed in such a manner that it is suitable for receiving the pressure compensation element 10 or for receiving the plastic part 14. The housing part 40 and the pressure compensation element 10 or the plastic part 14 may be connected to one another in a firmly bonded manner, advantageously via an adhesive connection. In particular, the adhesive connection is located between the circumferential collar of the plastic part 14 and the housing part 38.

The invention has been described above with reference to exemplary embodiments. It is understood that numerous amendments and modifications are possible, without departing from the scope of protection defined by the claims. A combination of the various exemplary embodiments is also possible.

1. A pressure compensation element having a plastic part and a membrane, wherein the plastic part has an upper and an underside and at least one hole extending from the upper to the underside, wherein the at least one hole is formed in an offset manner and/or at least one bridge-type element is arranged on the upper or the underside of the plastic part, and extends over the at least one hole.

2. The pressure compensation element according to claim 1, wherein the plastic part has a circumferential collar.

3. The pressure compensation element (10) according to claim 1, wherein the plastic part has at least one spacer element.

4. The pressure compensation element according to claim 1, wherein the plastic part has at least one circumferential groove and/or one circumferential lamella (30) which is arranged on the circumferential collar.

5. A sensor assembly comprising:
a housing part; and
a pressure compensation element having
a plastic part having a circumferential collar, and
a membrane,
wherein the plastic part has an upper and an underside and at least one hole extending from the upper to the underside, wherein the at least one hole is formed in an offset manner and/or at least one bridge-type element is arranged on the upper or the underside of the plastic part, and extends over the at least one hole;
wherein the housing part has a hole and the pressure compensation element is arranged in the hole.

6. The sensor assembly according to claim 5, wherein an adhesive connection is arranged between the circumferential collar of the plastic part and the housing part.

7. The sensor assembly according to claim 5, wherein the housing part is formed from a metal.

8. A sensor assembly having according to claim 5, further comprising a sensor element wherein the housing part encloses the sensor element.

9. The sensor assembly according to claim 8, wherein the sensor element is a radar sensor.

10. (canceled)
